(19) United States
(12) Patent Application Publication
(10) Pub. No.: US 2018/0122964 A1
(43) Pub. Date: May 3, 2018

(54) SOLAR BATTERY AND SOLAR BATTERY MODULE

(71) Applicant: Kaneka Corporation, Osaka (JP)

(72) Inventors: Daisuke Adachi, Osaka (JP); Tooru Irie, Osaka (JP); Toru Terashita, Osaka (JP)

(73) Assignee: Kaneka Corporation, Osaka (JP)

(21) Appl. No.: 15/856,911

(22) Filed: Dec. 28, 2017

Related U.S. Application Data
(63) Continuation of application No. PCT/JP2016/069471, filed on Jun. 30, 2016.

(30) Foreign Application Priority Data
Jun. 30, 2015 (JP) 2015-131638

(51) Int. Cl. H01L 31/0236; H01L 31/0224; H01L 31/0747; H01L 31/18; H01L 31/048

(52) U.S. Cl. CPC H01L 31/02363; H01L 31/022475; H01L 31/048; H01L 31/1884; H01L 31/022425; H01L 31/0747

(57) ABSTRACT

A solar cell includes: a cell main body part including a back electrode and a photoelectric conversion section, the back electrode being arranged on a back surface of the photoelectric conversion section; and a metal film disposed in contact with the back electrode of the cell main body part. The back electrode includes a plurality of projections or recesses with an arithmetic mean roughness of more than 0.1 μm. The metal film has an arithmetic mean roughness of more than 0.1 μm on a surface contacting the back electrode. The metal film covers at least 10% of a back surface of the cell main body part.

### TECHNICAL FIELD

The invention relates to a solar cell and solar cell module.

### BACKGROUND ART

In the solar cell, carriers (electrons and holes) generated by light irradiation on a photoelectric conversion section having a semiconductor junction are extracted to an external circuit to generate electricity. An electrode is provided on the photoelectric conversion section of the solar cell for efficiently extracting carriers generated at the photoelectric conversion section to the external circuit. For example, in a heterojunction solar cell having an amorphous silicon layer on a crystalline silicon substrate, a transparent conductive layer and a collecting electrode are provided as electrodes. Textured structures having a cross-sectionally triangular shape such as a pyramidal shape are formed on surfaces of a solar cell on the light-incident side and on the back side from the viewpoint of optical confinement etc.

When a solar cell is used as an electrical power source (energy source), the power per solar cell is at most several watts (W). Thus, in general, the solar cell is used in the form of a solar cell module in which a plurality of solar cells are electrically connected in series. By electrically connecting a plurality of solar cells in series, the voltages of the solar cells are added together, and therefore the power is increased.

The solar cell module has a configuration in which a plurality of solar cells are encapsulated between a light-incident side protecting member such as a glass plate and a back sheet (e.g., a laminated film with an aluminum foil or the like sandwiched between plastic films) with an encapsulant including EVA (ethylene-vinyl acetate copolymer) resin etc. Adjacent solar cells are electrically connected in series or in parallel through a wiring member including a copper foil etc.

For improving the efficiency of the solar cell module, it is effective to reduce the resistances of an electrode and a wiring member which serve as a current extraction path from a photoelectric conversion section. For example, Patent Document 1 discloses a configuration in which a solar cell is covered with a conductive sheet from the top (back side) of a wiring member (interconnector) connected to a back electrode of the solar cell. Patent Document 1 suggests that with this configuration, the conductive sheet serves as a current pass to contribute to reduction of resistance, and therefore the series resistance of a module can be reduced as in the case where the thickness of each of the back electrode and the wiring member is increased.

### PRIOR ART DOCUMENT

### Patent Document

Patent Document 1: JPA 2005-167158

### SUMMARY OF THE INVENTION

### Problems to be Solved by the Invention

The present inventors prepared a solar cell module with a metal film disposed so as to cover a back electrode of a solar cell as described in Patent Document 1, but series resistance was only slightly reduced. An object of the present invention is to provide a solar cell and a solar cell module which have small series resistance on the back side, and excellent conversion characteristics.

### Means for Solving the Problems

A solar cell of the present invention includes a cell main body part having a back electrode on a back surface of a photoelectric conversion section, and a metal film disposed in contact with the back electrode of the cell main body part. The metal film is disposed so as to cover a region occupying 10% or more of the back surface area of the cell main body part. The back electrode of the cell main body part has irregularity structures, such as a plurality of projections or recesses, with an arithmetic mean roughness of more than 0.1 μm. The arithmetic mean roughness of the contact surface of the metal film with the back electrode of the cell main body part is more than 0.1 μm. The arithmetic mean roughness of the contact surface of the metal film with the back electrode is preferably less than 10 μm.

In one embodiment, the cell main body part includes a crystalline silicon substrate in the photoelectric conversion section. The crystalline silicon substrate has pyramidal irregularity structures on a back surface thereof, such as a plurality of pyramidal projections or recesses (e.g., a textured surface comprising a plurality of pyramidal projections or recesses), and the irregularity structures of the back electrode of the cell main body part are formed so as to follow the irregularity structures on the back surface of the crystalline silicon substrate.

The present invention also relates to a solar cell module including the solar cell, a wiring member, back side protecting member and an encapsulant. In the solar cell module of the present invention, the wiring member is connected to a back surface of the cell main body part of the solar cell, and the encapsulant is disposed between the metal film of the solar cell and the back side protecting member.

In one embodiment, the metal film has an opening, and the encapsulant is in contact with the back surface of the cell main body part through the opening of the metal film.

### Effects of the Invention

According to the present invention, a back electrode of a solar cell has irregularity structures, and a metal film disposed in contact with the back electrode also has surface irregularities, so that the contact area between the back electrode and the metal film increases, leading to reduction of contact resistance. The metal film that is in contact with the back electrode of the solar cell serves as a main path of a current, and therefore a distance over which carriers move in a surface of the back electrode decreases. Thus, a series resistance component is reduced, leading to improvement conversion efficiency.

### BRIEF DESCRIPTION OF THE DRAWINGS

FIG. 1 is a sectional view of a solar cell module.

FIG. 2 is a sectional view of a solar cell string.

FIGS. 3A, 3B and 3C are conceptual views for illustrating irregularity structures of a back electrode.

FIG. 4A is a conceptual view for illustrating a contact state between a metal film and a cell main body part in a conventional technique.

FIG. 4B is a conceptual view for illustrating a contact state between a metal film and a cell main body part.

FIG. 4C is a conceptual view for illustrating a contact state between a metal film and a cell main body part, in which the metal film has large irregularity structures.

FIG. 5 is a sectional view of a part in the vicinity of an end of a solar cell in a solar cell module.

FIG. 6 is a sectional view of a solar cell module in which a metal film has an opening.

### MODE FOR CARRYING OUT THE INVENTION

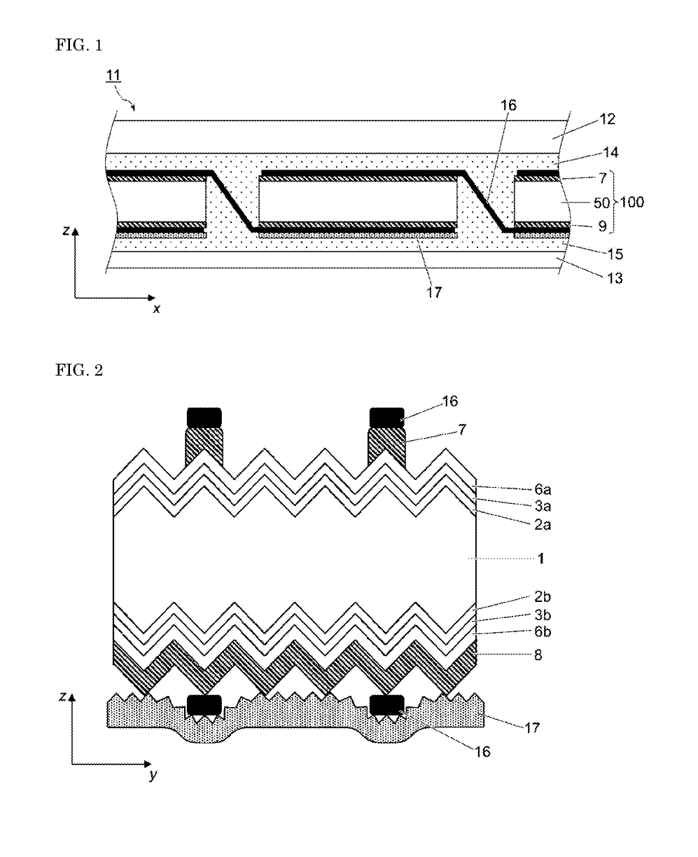

A solar cell module includes a solar cell, a wiring member, back side protecting member and an encapsulant, and a plurality of solar cells are connected through the wiring member. FIG. 1 is a sectional view of a solar cell module in an extending direction (x direction) of the wiring member.

FIG. 2 is a sectional view of a solar cell string in a cross-section (y-z plane) perpendicular to the extending direction (x direction) of the wiring member. The solar cell of the present invention includes a cell main body part 100 having a back electrode 9 on a back surface of a photoelectric conversion section 50, and a metal film 17 that is in contact with a back surface of the cell main body part 100. In the solar cell string, a wiring member 16 extending in the x direction is connected to a light-incident surface metal collecting electrode 7 and the back electrode 9 of the cell main body part, so that adjacent solar cells are electrically connected to each other.

[Cell Main Body Part]

The cell main body part includes a photoelectric conversion section and an electrode. FIG. 2 shows a heterojunction solar cell with the photoelectric conversion section 50 having a conductive silicon-based thin-film 3a on one surface (light-incident surface) of a single-crystalline silicon substrate 1 and having a conductive silicon-based thin-film 3b on the other surface (surface opposite to the light-incident side; also referred to as a back surface) of the single-crystalline silicon substrate 1. Intrinsic silicon-based thin-films 2a and 2b are disposed between the single-crystalline silicon substrate 1 and the conductive silicon-based thin-films 3a and 3b, respectively. A transparent electrode layer 6a and a metal collecting electrode 7 are disposed on the light-incident surface of the photoelectric conversion section 50, and a back electrode 9 is disposed on the back surface of the photoelectric conversion section 50.

(Photoelectric Conversion Section)

In the heterojunction solar cell, a single-crystalline silicon substrate of first conductivity-type is used as the silicon substrate 1. The “first conductivity-type” means one of an n-type and a p-type.

The silicon substrate 1 has irregularity structures on a surface thereof. Accordingly, irregularity structures following the irregularity structures of the silicon substrate are formed on surfaces of the silicon-based thin-film and the electrode layer formed on the crystalline silicon substrate. Preferably, the irregularity structures on the surface of the single-crystalline silicon substrate have a quadrangular-pyramidal shape (pyramidal shape). The irregularity structures may have a crater shape or the like. The irregularity structures are characterized by an arithmetic mean roughness Ra described in JIS B 0031 (1994).

Silicon-based thin-films are deposited on the single-crystalline silicon substrate. Examples of the silicon-based thin-film include an amorphous silicon thin-film and microcrystalline silicon thin-film (a thin-film including amorphous silicon and crystalline silicon). Among them, an amorphous silicon-based thin-film is preferably.

The intrinsic silicon-based thin-films 2a and 2b are preferably i-type hydrogenated amorphous silicon composed of silicon and hydrogen. When i-type hydrogenated amorphous silicon is formed on a single-crystalline silicon substrate by a CVD method, surface passivation can be effectively performed while suppressing diffusion of impurities to the single-crystalline silicon substrate. Conductive silicon-based thin-films 3a and 3b have different conductivity-types. In other words, one of the conductive silicon-based thin-films 3a and 3b is a p-type silicon-based thin-film, and the other is an n-type silicon-based thin-film.

The deposition method for forming the silicon-based thin-films is preferably a plasma-enhanced CVD method. As a dopant gas for forming p-type or n-type silicon-based thin-film, B₂H₆, PH₃, or the like is preferably used. When a gas containing a different element, such as CH₄, CO₂, NH₃ or GeH₄, is added in deposition of the conductive silicon-based thin-film, the silicon-based thin-film is alloyed so that the energy gaps of the silicon-based thin-film can be changed.

(Transparent Electrode Layer)

It is preferred that a heterojunction solar cell includes a transparent electrode layer 6a on the light-incident surface of the photoelectric conversion section 50 (on the conductive silicon-based thin-film 3a), and a transparent electrode layer 6b on the back surface of the photoelectric conversion section 50 (on the conductive silicon-based thin-film 3b). The transparent electrodes 6a and 6b include conductive oxide as a main component. As the conductive oxide, for example, zinc oxide, indium oxide, and tin oxide may be used alone or in mixtures thereof. Among them, indium-based oxides including indium oxide are preferable, and indium tin oxide (ITO) is particularly preferable.

The thickness of each of the transparent electrode layers 6a and 6b is preferably 10 to 140 nm. The back side transparent electrode layer 6b has a role of causing a current to pass from the photoelectric conversion section 50 to the back side metal electrode and the metal film, and a role of protecting the photoelectric conversion section 50. As described later, in the present invention, the metal film 17 is disposed in contact with the back surface of the cell main body part 100, and therefore a distance over which a current passes in a surface of the back side transparent electrode layer 6b can be reduced. Particularly, when the back side transparent electrode layer has a small thickness and large resistance in an in-plane direction, a current tends to easily pass to the metal film 17 having small resistance in the in-plane direction. For reducing the distance over which a current passes through the back side transparent electrode layer, the thickness of the back side transparent electrode layer 6b is preferably small.

The method for forming the transparent electrode layer is not particularly limited. For forming surface irregularity structures following the irregularity structures of the photoelectric conversion section on a surface of the transparent electrode layer, a physical vapor deposition method such as a sputtering method or an ion plating method is preferable.

(Light-Incident Surface Metal Collecting Electrode)

The patterned metal collecting electrode 7 is formed on the light-incident side-transparent electrode layer 6a. As a material of the collecting electrode 7, gold, silver, copper, aluminum or the like is used. Preferably, silver or copper is used from the viewpoint of an electrical conductivity. The collecting electrode 7 can be formed by an inkjet method, a screen printing method, a wire bonding method, a spraying method, a vacuum deposition method, a sputtering method or the like. Preferably, the patterned metal collecting electrode is formed by a screen printing method using a silver paste, or a plating method such as a copper electroplating from the viewpoint of productivity.

(Back Side Metal Electrode)

Preferably, the back side metal electrode 8 is provided on the back side transparent electrode layer 6b. By providing the back side metal electrode 8, contact resistance between the cell main body part 100 and the metal film 17 can be reduced. The back side metal electrode 8 may be disposed on the entire surface of the back side transparent electrode layer 6b, and may have the same pattern shape as that of the metal electrode on the light-incident side.

A surface of the back electrode 9 has irregularity structures with an arithmetic mean roughness Ra1 of more than 0.1 μm. The arithmetic mean roughness of the back electrode 9 is an arithmetic mean roughness of a region occupying a main part of the back surface area of the cell main body part 100. That is, in the case where the back side metal electrode 8 is disposed on the entire back surface of the back side transparent electrode layer 6b, the arithmetic mean roughness of the back side metal electrode 8 is the arithmetic mean roughness of the back electrode 9. In the case where a patterned back side metal electrode is provided on the back side transparent electrode layer 6b, the area of the patterned metal electrode is generally 10% or less of the total area, and therefore a main part of the back surface area is occupied by a region in which the metal electrode is not provided and the back side transparent electrode layer 6b is exposed. Thus, the arithmetic mean roughness of the back side transparent electrode layer 6b is the arithmetic mean roughness of the back electrode 9.

For increasing the number of apexes in irregularity structures, and increasing the contact area between the metal film 17 and the back electrode 9, the arithmetic mean roughness Ra1 of the back electrode 9 is preferably 5 μm or less, more preferably 3 μm or less. On the other hand, for obtaining an appropriate optical confinement effect, the arithmetic mean roughness Ra1 of the back electrode 9 is preferably 0.3 μm or more, more preferably 0.5 μm or more.

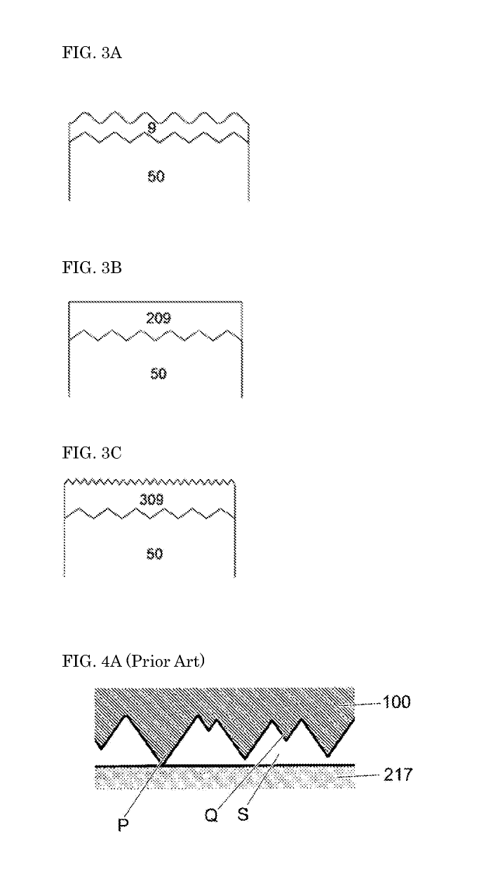

The back electrode 9 with irregularity structures can be provided by causing the surface shape of the back electrode 9 to follow irregularity structures of the back surface of the silicon substrate 1. The phrase “irregularity structures follows irregularity structures” means that the shapes of two irregularity structures correlate to each other as shown in FIG. 3(A).

The silicon-based thin-films 2b and 3b formed on the silicon substrate 1 has a sufficiently smaller thickness as compared to the size of the irregularities of the silicon substrate 1. Thus, the surface shape of the photoelectric conversion section 50 on the back side follows the irregularity structures of the back surface of the silicon substrate, and the arithmetic mean roughness of the back surface of the photoelectric conversion section is close to the arithmetic mean roughness of the back surface of the crystalline silicon substrate. Similarly, when the back electrode 9 has a sufficiently small thickness as compared to the irregularity structures of the back surface of the photoelectric conversion section (e.g., the thickness of the back electrode is not more than ⅓ of the arithmetic mean roughness of the back surface of the photoelectric conversion section), the surface shape of the back electrode follows the irregularity structures of the back surface of the photoelectric conversion section, and the arithmetic mean roughness of the back electrode is close to the arithmetic mean roughness of the back surface of the photoelectric conversion section. Therefore, the arithmetic mean roughness Ra1 of the back electrode is close to the arithmetic mean roughness of the back surface of the silicon substrate 1.

When the back side transparent electrode layer 6b is formed on the back surface of the photoelectric conversion section 50 by a physical vapor deposition method, the back side transparent electrode has irregularity structures following the irregularity structures of the back surface of the photoelectric conversion section 50 as described above. When the back electrode is formed on the entire surface of a back side transparent electrode layer 6b using a conductive paste, an electrode 209 having a smooth surface as shown in FIG. 3(B) is easily formed or an electrode 309 as shown in as shown in FIG. 3(C) which has irregularity structures with different irregularity sizes, irregularity cycles, irregularity shapes etc. from those of the irregularity structures of the photoelectric conversion section is easily formed due to a low correlation between the surface shape of the electrode 309 and the photoelectric conversion section. Thus, when a metal electrode is formed on the entire back surface, it is preferable to perform deposition by a physical vapor deposition method such as a sputtering method or an ion plating method.

The material of the back side metal electrode 8 is not particularly limited. When the back side metal electrode is deposited on the entire surface, a material having a low resistivity, and exhibiting a high reflectance to an infrared ray is preferable, and for example, silver, copper or the like is preferable. For reducing contact resistance, the thickness of the back side metal electrode is preferably 10 nm or more, more preferably 50 nm or more.

The back side metal electrode may have a single layer, or a plurality of stacked layers. For example, a metallic material having a high reflectance in a near-infrared or infrared range, such as silver, gold or aluminum, or a material having high conductivity and chemical stability may be used for a first back side metal electrode that is in contact with the back side transparent electrode layer 6b, and an inexpensive material such as aluminum or copper may be used for a second back side metal electrode on the first back side metal electrode. Further, a protecting metal layer having excellent chemical stability, such as titanium, tin or chromium, may be disposed on the second back side metal electrode. Examples of the stacking configuration of the back side metal electrode include a configuration in which a silver layer with a thickness of 8 to 50 nm is provided as the first back side metal electrode, a copper layer with a thickness of 2 to 100 nm is provided as the second back side metal electrode, and a metal layer of titanium, tin, chromium or the like with a thickness of 10 to 30 nm is provided as a protecting conductive layer on the second back side metal electrode.

The patterned back side metal electrode can be formed by a printing method such as screen printing, a plating method or the like, as with the metal collecting electrode 7 on the light-incident side. A metal electrode layer may be formed on the entire back surface by a sputtering method etc., followed by forming a patterned metal electrode on the metal electrode layer by a printing method or a plating method. Alternatively, a patterned metal electrode may be formed on the back side transparent electrode layer 6b, followed by forming an electrode on the entire back surface by a sputtering method or the like so as to cover the back side transparent electrode layer and the patterned metal electrode.

[Metal Film]

The solar cell of the present invention includes the metal film 17 that is in contact with the back electrode 9 of the cell main body part 100. As the metal film 17, a single-layer metal foil may be used, or a laminated of a plurality of metal foils may be used. An insulating support such as a PET film with a metal foil stacked thereon may also be used. When a metal film consisting of a stack of an insulating support and a metal foil is used, the metal film is disposed in such a manner that the metal foil is in contact with the cell main body part. As a metallic material of the metal film, aluminum, copper, silver, tin, titanium, nickel or an alloy thereof is applicable. A low-resistance metal such as copper or aluminum is preferable from the viewpoint of an electrical conductivity.

In the metal film 17, the contact surface with the cell main body part 100 is roughened. The surface of the metal film can be roughened by chemical etching or mechanical processing.

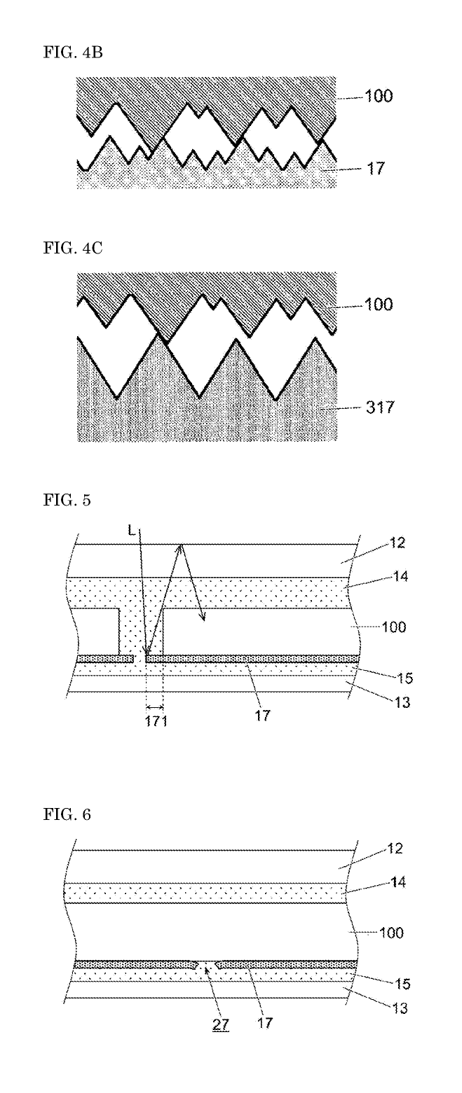

Irregularity structures formed by anisotropic etching of the single-crystalline silicon substrate generally have uneven irregularity sizes, and therefore the irregularity structures of the back surface of the cell main body part 100 formed so as to follow the irregularity structures of the single-crystalline silicon substrate are apt to have uneven irregularity sizes. When a flat metal film 217 is disposed on the back surface of the cell main body part 100 having uneven irregularity sizes, only an apex P of a large convex is in contact with the metal film, and an apex Q of a small convex is not in contact with the metal film, and allows a void S to exist between the irregularity structure and the metal film as schematically shown in FIG. 4A. Thus, the contact area between the metal film and the solar cell is very small, so that contact resistance increases.

On the other hand, when the surface of the metal film 17 is roughened, even a small convex of the back surface of the cell main body part has a contact point with the metal film as shown in FIG. 4B. Thus, the contact surface between the cell main body part having irregularity structures on the back surface and the metal film increases, so that contact resistance can be reduced. For increasing the contact area with the irregularity structures of the back surface (back electrode) of the cell main body part, the contact surface of the metal film with the cell main body part has irregularity structures with an arithmetic mean roughness Ra2 of more than 0.1 μm.

When the irregularity structures of the metal film have a large size, the density of apexes of irregularities of the metal film decreases, and therefore the number of contact points between the metal film and the back surface of the cell main body part tends to decrease, leading to reduction of the contact area between a metal film 317 and the cell main body part 100 as shown in FIG. 4C. Therefore, the arithmetic mean roughness Ra2 of the metal film is preferably 10 μm or less, more preferably 5 μm or less.

In a general solar cell in which a metal film is not provided on a back surface of a cell main body part, photocarriers generated in a photoelectric conversion section are recovered at a back electrode, and move in a surface of the back electrode, and flow into a wiring member. When the back side metal electrode is disposed on the entire surface, an electrical loss is easily generated due to resistance in the surface if the metal electrode has a small thickness. When the back side metal electrode is a pattern shape such as a grid shape, photocarriers generated in the photoelectric conversion section move in the in-plane direction of the back side transparent electrode layer, and are recovered at the metal electrode, and therefore the influence of in-plane resistance of the back electrode tends to be greater as compared to a case where the metal electrode is disposed on the entire surface.

The thickness of the metal film can be easily increased as compared to a back side metal electrode formed by a physical vapor deposition method such as a sputtering method, and resistance in the in-plane direction can be reduced. Further, the cost of the metal film is lower as compared to a patterned electrode formed from an Ag paste or the like. When the metal film is disposed on the back electrode in such a manner that the metal film is in contact with the back electrode, many of photocarriers generated in the photoelectric conversion section move through the surface of the low-resistance metal film and flow into the wiring member, so that the metal film serves as a main current path. Accordingly, a current passing through the back electrode decreases, so that an electrical loss caused by series resistance of the back electrode can be reduced. In the present invention, the surface of the metal film 17 is roughened, and the density of contact points of the cell main body part 100 with the back electrode 9 is high, so that the distance over which carriers move in the in-plane direction of the back electrode is small, leading to improvement of the effect of reducing series resistance by the metal film 17.

From the viewpoint of the effect of reducing a series resistance component, the thickness of the metal portion of the metal film 17 is preferably 0.5 μm or more, more preferably 1 μm or more, further preferably 5 μm or more. From the viewpoint of, for example, ease of handling in the production process, the thickness of the metal portion of the metal film is preferably 50 μm or less, more preferably 30 μm or less.

The metal film 17 is disposed so as to cover a region occupying 10% or more of the back surface area of the cell main body part 100. When the wiring member 16 is connected to the back electrode of the cell main body part, the back surface area of the cell main body part includes the area of a region provided with the wiring member. For further reducing the series resistance component, the ratio of the area of a region covered with the metal film 17 to the back surface area of the cell main body part is preferably 50% or more, more preferably 80% or more, further preferably 90% or more. Preferably, the metal film is disposed so as to cover the entire back surface of the cell main body part. The metal film 17 that is in contact with one cell main body part may be a single sheet, or a plurality of sheets may be separately disposed on the back surface of the cell main body part.

[Solar Cell Module]

As shown in FIG. 1, the wiring member 16 is connected to the back surface of the cell main body part 100, and the cell main body part 100 to which the wiring member 16 is connected, and the metal film 17 are disposed between the light-incident surface encapsulant 14 and the back side encapsulant 15, and encapsulated to modularize solar cells.

The wiring member 16 serves to connect adjacent solar cells, or connect a solar cell to an external circuit. The wiring member is a thin plate composed of a metal such as copper. The wiring member 16 may have irregularity structures on a contact surface with the back surface of the solar cell (i.e., on a light-incident surface). Preferably, the wiring member is connected to the cell main body part with a solder, a conductive adhesive, a conductive film or the like interposed therebetween.

Electrical connection between adjacent solar cells may be series connection or parallel connection. The back electrode 9 of a solar cell is connected to the metal collecting electrode 7 on a light-incident surface of an adjacent solar cell through the wiring member 16 to connect the two cells in series.

Preferably, the metal film 17 is disposed so as to cover the wiring member. In other words, it is preferable that the wiring member is connected to the cell main body part 100, and the metal film 17 is brought into contact with the wiring member from above. In this embodiment, the back electrode 9, the wiring member 16 and the metal film 17 are sequentially disposed, and the metal film 17 is in contact with the wiring member 16 in a region to which the wiring member is connected on the back side of the solar cell module. The region of the back surface of the cell main body part, to which the wiring member is connected, usually occupies less than 10% of the total area. In other regions, the metal film 17 is disposed in contact with the back electrode 9.

As shown in FIG. 5, the metal film 17 may be disposed so as to protrude from the cell main body part. When a region 171 (protruding section) with the metal film disposed so as to protrude into a gap between adjacent solar cells is present in a solar cell module in which a plurality of solar cells are connected, light incident to the gap between the solar cells is reflected to the incident side. Since the metal film 17 has irregularity structures on the light-incident side, light L reflected at the metal film protruding section 171 is easily irregularly reflected to the light-incident side, and reflected again at the interface between the light-incident side protecting member 12 of the module and air to be incident again from the light-incident surface of the solar cell. Thus, improvement of the light utilization efficiency of the solar cell module can be expected. Preferably, the metal film protruding section is provided so as not to cause a short circuit with an adjacent solar cell.

When the metal electrode on the back surface has a grid shape and the back side protecting member 13 has a low light reflectance, an effect of increasing a short circuit current is easily obtained by introducing the metal film 17 having a high reflectance. Specifically, the effect of increasing a short circuit current is easily obtained when the reflectance of the back side protecting member in an infrared range (e.g., an average reflectance to light having a wavelength of 0.8 to 1.2 μm) is 90% or less, and the effect of increasing a short circuit current is more easily obtained when the reflectance of the back side protecting member in an infrared range is 80% or less. The effect of increasing a short circuit current is easily obtained particularly when a black back side protecting member is used.

Preferably, the metal film 17 is disposed so as to cover the wiring member 16 connected to the back electrode. When the metal film 17 is disposed so as to cover the wiring member 16, the wiring member 16 is in contact with the metal film 17 in a region provided with the wiring member, and the back electrode 9 of the cell main body part 100 is in contact with the metal film 17 in other regions. In this case, carriers moving to the metal film 17 at the contact point between the back electrode 9 and the metal film 17 move in the surface of the metal film 17, and flow into the wiring member 16, and therefore series resistance can be reduced.

In a region to which the wiring member 16 is connected, the metal film 17 is not provided, and the metal film 17 and the wiring member 16 may be separated from each other.

The metal film may be made to have a function as a wiring member rather than connecting the wiring member to the back side of the cell main body part. For example, when a wiring member connected to an electrode on the light-incident surface of an adjacent solar cell is connected to a metal film protruding section as shown in FIG. 5, adjacent solar cells can be electrically connected through the metal film. This mode is preferable from the viewpoint of productivity because it is unnecessary to dispose a wiring member on the back surface of the cell main body part.

The metal film may have a slit or an opening. By using the metal film with a slit or an opening, ingress of bubbles between the cell main body part and the metal film can be suppressed in encapsulation. As shown in FIG. 6, an encapsulant flows between an encapsulant and an electrode layer from an opening 27 of the metal film, and thus the metal film 17 is sandwiched between encapsulants 15, so that the metal film 17 can be more firmly fixed to the back surface of the cell main body part 100.

When the back electrode 9 has no metal electrode and includes only transparent electrode, light (mainly infrared light) reaching the back side without being absorbed in the photoelectric conversion section is reflected at the metal film 17, and incident to the photoelectric conversion section again. When the metal film has irregularity structures, light is scattered and reflected at a wide angle, and therefore the optical path length of light incident to the cell again tends to increase, leading to an increase in short circuit current. The effect of increasing a short circuit current is more remarkably exhibited when the silicon substrate has a small thickness. Specifically, the effect of increasing a short circuit current is easily obtained when the average thickness of the silicon substrate is 150 μm or less, and the effect is remarkably exhibited when the average thickness of the silicon substrate is 100 μm or less.

When the arithmetic mean roughness Ra1 of the irregularity structures of the back surface of the cell main body part is smaller than the wavelength of light passing through the cell main body part, light is hardly scattered at the back surface of the cell main body part. When light passing through the cell main body part is scattered by the metal film having irregularity structures, the effect of increasing a short circuit current is easily obtained. Specifically, the effect of increasing a short circuit current is easily obtained when the arithmetic mean roughness Ra1 is 1 μm or less, and the effect is remarkably exhibited when the arithmetic mean roughness Ra1 is 0.5 μm or less.

Although an example of a heterojunction solar cell having an electrode on each of both surfaces of a cell main body part is mainly described above, the present invention is also applicable to, for example, a back-contact-type solar cell in which an electrode is disposed only on the back side, and a metal-wrap-through-type solar cell in which interconnection portions with an adjacent solar cell are collected on a back surface.

The solar cell is not limited to heterojunction solar cell, and various kinds of solar cells are applicable. Examples of solar cells include: crystalline silicon solar cells other than the heterojunction solar cell; solar cells using a semiconductor substrate other than silicon, such as GaAs; silicon-based thin-film solar cells having a transparent electrode layer on a pin junction or a pn junction of an amorphous silicon-based thin-film or a crystalline silicon-based thin-film, compound semiconductor solar cells such as CIS and GIGS; organic thin-film solar cells such as dye sensitizing solar cell and one using an organic thin-film (conductive polymer).

### EXAMPLE

[Preparation of Cell Main Body Part]

### (Preparation of Photoelectric Conversion Section)

An n-type single-crystal silicon wafer having a light-incident surface direction identical to the (100) surface and having a thickness of 200 μm was immersed in a 2 wt % aqueous HF solution for 3 minutes to remove silicon oxide covering on the surface, and thereafter rinsed twice with ultrapure water. The silicon substrate was immersed in a 5/15 wt % aqueous KOH/isopropyl alcohol solution held at 70° C. for 15 minutes, and the surface of the wafer was etched to form a texture. Thereafter, the wafer was rinsed twice with ultrapure water. The surface of the wafer was observed using an atomic force microscope (AFM manufactured by Pacific Nanotechnology, Inc.), and it was confirmed that the surface of the wafer was etched, and a pyramidal irregularity structure (texture) exposed at the (111) plane was formed. The arithmetic mean roughness of the each surfaces of the wafer was about 2 μm.

The wafer after etching was introduced into a CVD apparatus, and at the light-incident side thereof, i-type amorphous silicon was formed to have a thickness of 5 nm. Deposition conditions of the i-type amorphous silicon included a substrate temperature of 170° C., a pressure of 100 Pa, a SiH₄/H₂ flow ratio of 3/10 and a power density supply of 0.011 W/cm². The thickness of the thin-film in this example is a value calculated from a deposition rate determined by measuring the thickness of a thin-film formed on a glass substrate under the same conditions using a spectroscopic ellipsometry (trade name: M2000, manufactured by J.A. Woollam Co. Inc.).

On the i-type amorphous silicon layer, p-type amorphous silicon was formed to have a thickness of 7 nm. Deposition conditions of the p-type amorphous silicon layer included a substrate temperature of 170° C., a pressure of 60 Pa, a SiH₄/B₂H₆ flow ratio of 1/3 and a power density supply of 0.01 W/cm². The B₂H₆ gas flow rate mentioned above is a flow rate of a diluting gas wherein B₂H₆ was diluted to concentration of 5000 ppm using H₂ gas.

Thereafter, on the back side of the wafer, an i-type amorphous silicon layer was formed to have a thickness of 6 nm with deposition conditions identical to those for the light-incident side i-type amorphous silicon layer. On the i-type amorphous silicon layer, an n-type amorphous silicon layer was formed to have a thickness of 4 nm. Deposition conditions of the n-type amorphous silicon layer included a substrate temperature of 170° C., a pressure of 60 Pa, a SiH₄/PH₃ flow ratio of 1/2 and a power density supply of 0.01 W/cm². The PH₃ gas flow rate mentioned above is a flow rate of a diluting gas wherein PH₃ concentration was diluted to 5000 ppm using H₂ gas.

In the manner described above, a photoelectric conversion section for a heterojunction solar cell was prepared. The arithmetic mean roughness of the back surface (n-type amorphous silicon layer) of the photoelectric conversion section was about 2 μm, and irregularity structures following the irregularity structures of the back surface of the silicon wafer was formed.

(Formation of Electrode)

On each of the light-incident surface and back surface of the photoelectric conversion section, indium tin oxide (ITO, refractive index: 1.9) as a transparent electrode layer was deposited with a thickness of 100 nm. The transparent electrode layer was formed by applying a power density of 0.5 W/cm² in an argon atmosphere at a substrate temperature of room temperature and a pressure of 0.2 Pa using indium tin oxide as a target.

An Ag paste was printed on the transparent electrode layer on the light-incident side by a screen printing method to form a grid-shaped metal collecting electrode including bus bar electrodes 21, and finger thin lines orthogonally crossing bus bar electrodes 21.

On the entire back surface of the back side transparent electrode layer, a 100 nm-thick silver layer, a 250 nm-thick copper layer and a 10 nm-thick titanium layer were formed by a sputtering method. The thickness of the back electrode was measured by observing a cross-section of the solar cell using a SEM (Field Emission Scanning Electron Microscope 54800 manufactured by Hitachi High-Technologies Corporation.). The arithmetic mean roughness Ra1 of the surface of the back electrode was 2 μm, and irregularity structures following the irregularity structures of the back surface (n-type amorphous silicon layer) of the photoelectric conversion section was formed.

Laser light (third harmonic wave of YAG laser: wavelength 355 nm) was applied from the light-incident surface of the wafer after formation of the electrode to form a groove over the entire outer peripheral part. The groove was positioned at 0.5 mm from the end of the wafer, and the depth of the groove was set to about ⅓ of the thickness of the crystalline silicon substrate. Subsequently, the wafer was cleaved by bending the wafer along the groove, the outer peripheral part of the wafer was removed to eliminate short circuit portions of thin-films on front and back sides, and an insulation process was carried out.

In the following Examples (except for Example 5) and Comparative Examples, the cell main body part obtained as described above was used, a plurality of solar cells were connected through a wiring member to prepare a solar cell string, and encapsulation was performed to prepare a solar cell module.

### Example 1

A wiring member was disposed on the bus bar electrode of the correcting electrode and on the back electrode with a conductive film interposed therebetween, and a pressure of 2 MPa was applied at a temperature of 180° C. for 15 seconds to connect the electrode of the solar cell to the wiring member, thereby preparing a solar cell string in which a plurality of solar cells were connected in series. As the conductive film, one in which a resin matrix mainly composed of an epoxy resin contained 10% by mass of Ni particles having an average particle size of 10 μm was used.

A metal film was provided by cutting a copper foil roughened at one surface by chemical etching (thickness: 12 μm, arithmetic mean roughness of roughened surface: Ra2=3 μm) to have a width smaller than a distance between wiring members.

A white glass plate was used as a light-incident side protecting member, a 450 μm-thick EVA sheet was used as each of a light-incident side encapsulant and a back side encapsulant, a 30 μm-thick single-layer film of PET (polyethylene terephthalate) was used as a back side protecting member, and the white glass plate, the EVA sheet, the solar cell string, the metal film, the EVA sheet and the PET film were stacked in this order. The metal film was disposed between two wiring members and between the wiring member and the end portion of the substrate, and the wiring member and the metal film were separated from each other. This was subjected to thermocompression at atmospheric pressure for 5 minutes, and then held at 150° C. for 60 minutes to crosslink the EVA resin, and encapsulation was performed to obtain a solar cell module.

### Example 2

Except that the metal film width was reduced, and the metal film was disposed so as to cover a region occupying 30% of the area on the back side, the same procedure as in Example 1 was carried out to prepare a solar cell module.

### Example 3

Except that conditions for chemical etching of a copper foil were changed to set the arithmetic mean roughness Ra2 of the roughened surface to 0.8 μm, the same procedure as in Example 1 was carried out to prepare a solar cell module.

### Example 4

Except that a copper foil was used in which the arithmetic mean roughness Ra2 of the surface was set to 12 μm by press-processing the copper foil, the same procedure as in Example 1 was carried out to prepare a solar cell module.

### Example 5

In formation of an electrode in a cell main body part, a metal electrode was not formed on a transparent electrode layer on the back side, and the transparent electrode layer was set to an outermost surface layer on the back side of the cell main body part. Except that this cell main body part was used, a wiring member was connected onto the back side transparent electrode layer with a conductive film interposed therebetween, and a metal foil was placed on the wiring member, the same procedure as in Example 1 was carried out to prepare a solar cell module.

### Comparative Example 1

Except that a flat copper foil (arithmetic mean roughness Ra2<0.01 μm), the surface of which was not roughened, was used, the same procedure as in Example 1 was carried out to prepare a solar cell module, and the characteristics thereof were evaluated.

### Comparative Example 2

After a wiring member was connected in the same manner as in Example 1, a metal film was not introduced, and a white glass plate, an EVA sheet, a solar cell string, an EVA sheet and a PET film were stacked in this order, and encapsulated to obtain a solar cell module.

[Evaluation]

Using a solar simulator, pseudo-sunlight with an AM 1.5 spectrum distribution was applied with an energy density of 100 mW/cm² at 25° C., and the power generation characteristics of the solar cell modules of the Examples and Comparative Examples were measured. The configurations and power generation characteristics of the solar cell modules of Examples and Comparative Examples are shown in Table 1. There was no clear difference in open circuit voltage Voc and short circuit current Isc among Examples and Comparative Examples. Therefore, in Table 1, only the fill factors FF in Examples and Comparative Examples are compared. The fill factors FF in Table 1 are each shown as a value relative to a value in Comparative Example 1 where the value in Comparative Example 1 is set to 1.

TABLE 1

| | cell main body part | Metal film | | Power generation |
|---|---|---|---|---|
| | Back electrode | Ra2 | Formation | characteristics |
| | structure | (μm) | area | FF |
| Example 1 | transparent | 3 | 90% | 1.03 |
| | electrode/metal | | | |
| | electrode | | | |
| Example 2 | transparent | 3 | 30% | 1.01 |
| | electrode/metal | | | |
| | electrode | | | |
| Example 3 | transparent | 0.8 | 90% | 1.03 |
| | electrode/metal | | | |
| | electrode | | | |
| Example 4 | transparent | 12 | 90% | 1.01 |
| | electrode/metal | | | |
| | electrode | | | |
| Example5 | transparent | 3 | 90% | 1.02 |
| | electrode | | | |
| Comparative | transparent | <0.01 | 90% | 1.00 |
| Example 1 | electrode/metal | | | |
| | electrode | | | |

| | | | |
|---|---|---|---|
| Comparative | transparent | — | 1 |
| Example 2 | electrode/metal | | |
| | electrode | | |

In Comparative Example 1 where a copper foil having a flat surface was disposed on a back electrode, the value of the fill factor FF was identical to that in Comparative Example 2 where a metal film was not used, and an improvement of fill factor FF was not exhibited. On the other hand, Examples 1 to 4 where a copper foil having a roughened surface was disposed on a back side metal electrode in such a manner that the copper was in contact with the back side metal electrode each showed a fill factor FF higher than that in Comparative Example 2. In Example 5 where a metal film was disposed directly on a transparent electrode without providing a metal electrode on the transparent electrode, the fill factor FF was improved. These results indicate that the fill factor FF was improved because by using a metal film having a roughened surface, contact resistance between the back electrode and the metal film was decreased, so that a current on the back side passed to the metal film in a large amount, resulting in reduction of an electrical loss.

From comparison between Example 1 and Example 2, it is apparent that Example 1 where the area of a metal film-formed region was larger showed a higher fill factor FF. Example 4 where a copper foil having a large arithmetic mean roughness Ra2 was used showed a smaller fill factor FF as compared to Example 1. This may be because the contact area between the copper foil used in Example 4 and the back electrode decreased.

The above results show that when a metal film having a roughened surface is brought into contact with a back electrode of a solar cell, and the contact area is increased, a solar cell module having small resistance and excellent conversion characteristics is obtained.

### DESCRIPTION OF REFERENCE CHARACTERS

1 silicon substrate
2a, 2b intrinsic silicon-based thin-film
3a, 3b conductive silicon-based thin-film
6a, 6b transparent electrode layer
7 metal collecting electrode
8 back side metal electrode
9 back electrode
11 solar cell module
12 light-incident side protecting member
13 back side protecting member
14, 15 encapsulant
16 wiring member
17 metal film
50 photoelectric conversion section
100 cell main body part

What is claimed is:

1. A solar cell comprising:
a cell main body part comprising a back electrode and a photoelectric conversion section, the back electrode being arranged on a back surface of the photoelectric conversion section; and
a metal film disposed in contact with the back electrode of the cell main body part, wherein
the back electrode comprises a plurality of projections or recesses with an arithmetic mean roughness of more than 0.1 μm,
the metal film has an arithmetic mean roughness of more than 0.1 μm on a surface contacting the back electrode, and
the metal film covers at least 10% of a back surface of the cell main body part.

2. The solar cell according to claim 1, wherein
the photoelectric conversion section comprises a crystalline silicon substrate having a back surface comprising a plurality of pyramidal projections or recesses, and
the projections or recesses of the back electrode follow the pyramidal projections or recesses on the back surface of the crystalline silicon substrate.

3. The solar cell according to claim 1, wherein the arithmetic mean roughness of the metal film is more than 0.1 μm to less than 10 μm.

4. The solar cell according to claim 2, wherein the arithmetic mean roughness of the metal film is more than 0.1 μm to less than 10 μm.

5. A solar cell module comprising:
a solar cell;
a wiring member;
a back side protecting member; and
an encapsulant, wherein
the solar cell comprises:
a cell main body part comprising a back electrode and a photoelectric conversion section, the back electrode being arranged on a back surface of the photoelectric conversion section; and
a metal film disposed in contact with the back electrode of the cell main body part, and wherein
the back electrode comprises a plurality of projections or recesses with an arithmetic mean roughness of more than 0.1 μm,
the metal film has an arithmetic mean roughness of more than 0.1 μm on a surface contacting the back electrode,
the metal film covers at least 10% of a back surface of the cell main body part,
the wiring member is connected to the back surface of the cell main body part, and
the encapsulant is disposed between the metal film and the back side protecting member.

6. The solar module according to claim 5, wherein
the photoelectric conversion section comprises a crystalline silicon substrate having a back surface comprising a plurality of pyramidal projections or recesses, and
the projections or recesses of the back electrode follow the pyramidal projections or recesses on the back surface of the crystalline silicon substrate.

7. The solar cell according to claim 5, wherein the arithmetic mean roughness of the metal film is more than 0.1 μm to less than 10 μm.

8. The solar cell according to claim 6, wherein the arithmetic mean roughness of the metal film is more than 0.1 μm to less than 10 μm.

9. The solar cell module according to claim 5, wherein
an opening is provided in the metal film, and
the encapsulant is in contact with the cell main body part through the opening of the metal film.

10. The solar cell module according to claim 6, wherein
an opening is provided in the metal film, and
the encapsulant is in contact with the cell main body part through the opening of the metal film.

11. The solar cell module according to claim 7, wherein
an opening is provided in the metal film, and
the encapsulant is in contact with the cell main body part through the opening of the metal film.

12. The solar cell module according to claim 8, wherein
an opening is provided in the metal film, and
the encapsulant is in contact with the cell main body part through the opening of the metal film.
